(19) United States
(12) Patent Application Publication
(10) Pub. No.: US 2007/0231605 A1
(43) Pub. Date: Oct. 4, 2007

(54) Light-Emitting Device

(76) Inventor: Scott Watkins, Williamstown (AU)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/597,394

(22) PCT Filed: May 16, 2005
(86) PCT No.: PCT/GB05/01870

§ 371 Date: Nov. 22, 2006

(30) Foreign Application Priority Data
May 24, 2004 (GB) 0411580.4

(51) Int. Cl. H01L 51/30

(52) U.S. Cl. 428/704; 252/301.16; 252/301.35; 29/592.1; 568/12

(57) ABSTRACT

A light emitting device comprising: an anode; a cathode; a light emissive layer located between the anode and the cathode, said light emissive layer comprising a metal complex for emitting light; the metal complex comprising the group having general formula I:M-L(I) where M is a metal and L is a ligand, and L comprises Ar which is a substituted or unsubstituted heteroaryl ring; characterized in that the heteroaryl ring contains at least one phosphorous atom.

The present invention relates to a light-emitting device (LED) containing a metal complex and to a method of making the same. The present invention also relates to a new use for a metal complex; and to new metal complexes and to new compositions containing metal complexes.

In the last decade, much effort has been devoted to the improvement of the emission efficiency of light-emitting devices (LEDs) either by developing highly efficient materials or efficient device structures.

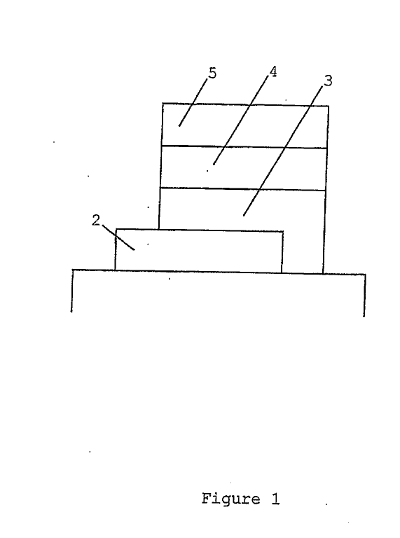

FIG. 1 shows a cross section of a typical LED. The device has an anode 2, a cathode 5 and a light emissive layer 4 located between the anode and the cathode. The anode may be, for example, a layer of transparent indium-tin oxide. The cathode may be, for example, LiAl. Holes and electrons that are injected into the device recombine radiatively in the light emissive layer. A further feature of the device is the optional hole transport layer 3. The hole transport layer may be a layer of polyethylene dioxythiophene (PEDOT), for example. This provides an energy level which helps the holes injected from the anode to reach the light emissive layer.

Known LED structures also may have an electron transport layer situated between the cathode 5 and the light emissive layer 4. This provides an energy level which helps the electrons injected from the cathode to reach the light emissive layer.

In an LED, the electrons and holes that are injected from the opposite electrodes are combined to form two types of excitons; spin-symmetric triplets and spin-antisymmetric singlets. Radiative decay from the singlets (fluorescence) is fast, but from the triplets (phosphorescence) it is formally forbidden by the requirement of the spin conservation.

In the past few years, many have studied the incorporation by blending of phosphorescent materials into the light emissive layer. Often, the phosphorescent material is a metal complex, however it is not so limited. Further, complexes of lighter metals are typically are fluorescent.

A metal complex will comprise a metal ion surrounded by ligands. A ligand in a metal complex can have several roles. The ligand can be an “emissive” ligand which accepts electrons from the metal and then emits light. Alternatively, the ligand may be present simply in order to influence the energy levels of the metal to prevent energy loss via non-radiative decay pathways. For example, where emission is from a ligand, it is advantageous to have strong field ligands coordinated to the metal to prevent energy loss via non-radiative decay pathways. Common strong field ligands are known to those skilled in this art and include CO, PPh₃, and ligands where a negatively charged carbon atom bonds to the metal. N-donor ligands are also strong field ligands, although less so than those previously mentioned.

The effect of strong field ligands can be appreciated from an understanding of the mechanism by which light is emitted from a metal complex. Three reviews of luminescent metal complexes that provide an appreciation of this mechanism are referred to below.

Chem. Rev., 1987, 87, 711-7434 is concerned with the luminescence properties of organometallic complexes. This review paper provides a brief summary of the excited states commonly found in organometallic complexes. The excited States that are discussed include metal-to-ligand charge-transfer (MLCT) states, which involve electronic transitions from a metal-centered orbital to a ligand-localized orbital. Thus, in a formal sense this excitation results in metal oxidation and ligand reduction. These transitions are commonly observed in organometallic complexes because of the low-valent nature of the metal centre and the low-energy position of the acceptor orbitals in many ligands. Ligand to metal charge-transfer (LMCT) states also are mentioned which involve electronic transitions from a ligand-localized orbital to a metal-centered orbital.

In the section of the article that deals with photoluminescence, a sub-section is dedicated to metal carbonyl complexes, which are said to be recognized as being some of the most light-sensitive inorganic materials. Examples include M(CO)⁻₆ (M=V, Nb, Ta); and M(CO)₆ (M=Cr, Mo, W).

Matrix isolation studies of M(CO)₅L complexes, where M=Mo or W and L=pyridine, 3-bromopyridine, pyridazine, piperidine, trimethylphosphine, or trichlorophosphine, are reported also as they are said to have provided the first reports of fluorescence from substituted metal carbonyls.

Several Mo(CO)₅L complexes, where L=a substituted pyridine ligand, are also mentioned and it is said that they are known to luminesce under fluid conditions. The emission has been assigned to a low-lying MLCT excited state

Other sub-sections in this review article are dedicated to dinitrogen complexes; metallocenes; metal isocyanides; alkenes; and ortho-metallated complexes.

It is said that a number of examples of ortho-metallated complexes have been shown to luminesce in room temperature solutions. For example, the emission spectrum of [Ru(bpy)₂(NPP)]⁺ is said to exhibit the structure associated with MLCT emission. Several ortho-metallated Pt(II) complexes also are mentioned where it is said that the emission may be assigned to a MLCT excited state.

The review article summarises that low-lying MLCT excited states are often observed, because of the low-valent metal centres and vacant low-energy ligand acceptor orbitals in organometallic complexes. Further, it is reported that relationships exist between the energy ordering of the excited-state levels and the observed photophysical and photochemical properties. Still further, it is said that the great majority of examples of room temperature emission have been attributed to MLCT excited states.

Analytical Chemistry, Vol. 63, NO, 17, Sep. 1, 1991, 829A to 837A is concerned with the design and applications of highly luminescent transition metal complexes especially those with platinum metals (Ru, Os, Re, Rh and Ir).

Table I lists representative metal complexes categorized by luminescence efficiency. The systems are limited to those containing at least one α-diimine ligand such as 2,2′-bipyridine (bpy) or 1,10-phenanthroline (phen), although many of the design rules and fundamental principles are said to apply to other classes of luminescent metal complexes.

In this paper it is explained that transition metal complexes are characterized by partially filled d orbitals and that to a considerable extent the ordering and occupancy of these orbitals determine emissive properties.

For a representative octahedral MX₆ d⁶ metal complex, where M is the metal and X is a ligand that coordinates at one site, it is explained that the octahedral crystal field of the ligands splits the five degenerate d orbitals into a triply degenerate t level and a doubly degenerate e level. The magnitude of the splitting is given by the crystal field splitting, which is a particularly important parameter for determining the luminescence properties of the complex, whose size is determined by the crystal field strength of the ligands and the central metal ion. The luminescence properties of the complex thus can be controlled by altering the ligand, geometry, and metal ion.

There are three types of excited states mentioned in this paper: metal-centred d-d states, ligand-based π-π* states, and charge-transfer states.

Charge-transfer (CT) states involve both the organic ligand and the metal. As mentioned above, metal-to-ligand charge transfer (MLCT) involves promoting an electron from a metal orbital to a ligand orbital and ligand-to-metal charge transfer (LMCT) involves promoting an electron from a ligand to a metal orbital.

According to this paper, the most important design rule of luminescent transition metal complexes is that the emission always arises from the lowest excited state. Thus control of the luminescence properties of complexes hinges on control of the relative state energies and the nature and energy of the lowest excited state. In this regard, the paper states that any metal-centred d-d states must be well above the emitting level to prevent their thermal excitation, which would result in photochemical instability and rapid excited-state decay. Therefore, one of the more important criteria is to remove the lowest d-d state from competition with the emitting level. Thus a desirable design goal is to make the d-d state as thermally inaccessible as possible from the emitting MLCT or π-π* state. Controlling the energies of the d-d states is accomplished by varying either the ligands or the central metal ion to affect the crystal field splitting. Stronger crystal field strength ligands or metals raise d-d state energies, and crystal field strength increases in the series
Cl<py<<bpy, phen<CN<CO
where py represents pyridine.

For a metal, the crystal field splitting increases when descending a column in the periodic table. CT state energies are affected by the ease of oxidation/reduction of the ligands and metal ion. For MLCT transitions, more easily reduced ligands and more easily oxidated metals lower the MLCT states.

The π-π* state energies are largely dictated by the ligands themselves. However, the energies and intensities of the π-π* transitions can be altered by varying either the substituents, the heteroatoms in the aromatic ring, or the extent of π conjugation.

Photochemistry And Luminescence Of Cyclometallated Complexes, Advances in Photochemistry, Volume 17, 1992, page 1 to 68 describes that most of the attention in this field has been focussed on complexes of the polypyridine-type family (prototype: Ru(bpy)²⁺₃, where bpy=2,2′ bipyridine).

The interest in the photochemical and photophysical properties of cyclometallated complexes is said to be an extension of this.

Table 2 in this publication shows absorption and emission properties of cyclometallated ruthenium, rhodium, iridium, palladium and platinum complexes and their ligands. Some of the complexes are charged and some are neutral.

A ligand in a metal complex can have several roles. The ligand can be an “emissive” ligand which accepts electrons from the metal and then emits light. Alternatively, the ligand may be present simply in order to influence the energy levels of the metal. For example, where emission is from a ligand, it is advantageous to have strong field ligands coordinated to the metal as discussed above. Common strong field ligands are known to those skilled in this art and include CO, PPh₃, and ligands where a negatively charged carbon atom bonds to the metal. N-donor ligands are also strong field ligands, although less so than those previously mentioned. In N-donor ligands, the nitrogen atom typically is part of a heteroaryl ring.

Typical N-donor ligands offer an advantage over CO ligands, for example because they offer the opportunity to functionalise the ligand. Specific functionalities can be introduced to the system by way of functional substituents such as solubilising substituents and charge-transporting substituents. Altering the substituents also gives control over the pi acceptor and sigma donor properties of the ligand which in turn influence the various energy levels and hence the colour and efficiency of emission.

In view of the above, it will be appreciated that there is a need to identify and design new, stable metal complexes for use in LEDs which provide opportunities for improving efficiency, colour and introducing functionality.

Therefore, it is an aim of the present invention to provide new metal complexes that can be used to emit light in an LED.

As such, in a first aspect of the present invention there is provided a light-emitting device comprising: an anode; a cathode; a light emissive layer located between the anode and the cathode, and said light emissive layer comprising a metal complex for emitting light; the metal complex comprising the group having general formula I:
M-L (I)
where M is a metal and L is a ligand, and L comprises Ar which is a substituted or unsubstituted heteroaryl ring; characterised in that the heteroaryl ring contains at least one phosphorous atom.

In a second aspect of the present invention, there is provided a method of making a light emitting device as defined in relation to the first aspect of the present invention, comprising the steps of forming the anode, the cathode and the light emissive layer so that the light emissive layer is located between the anode and the cathode.

In a third aspect of the present invention, there is provided the use of the metal complex as defined in relation to the first aspect of the present invention for emitting light.

In a fourth aspect of the present invention, there is provided a blend comprising a metal complex as defined in relation to the first aspect of the present invention and a host material.

In a fifth aspect of the present invention, there is provided a polymer or dendrimer containing a metal complex as defined in relation the first aspect of the present invention.

In a sixth aspect of the present invention, there is provided a metal complex comprising the group having general formula I:
M-L (I)
where M is the metal and L is a ligand, and L comprises a group having general formula XII or XIII where L is directly coordinated to M in the metal complex by the positions shown 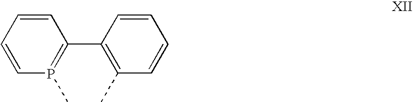
which is substituted or unsubstituted 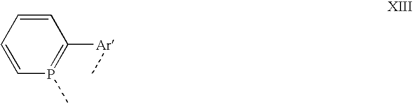
which is substituted or unsubstituted and where Ar′ is a 5 membered aryl or heteroaryl ring.

Turning to the first aspect of the present invention, preferably, Ar is coordinated directly to M in the metal complex. One such metal complex that can be used in an LED according to the present invention is known from Chem. Ber. 1996, 129, 263-268 “Phosphorous Analogs of Bipyridines: Their Synthesis and Coordination Chemistry”. This paper is concerned with the synthesis and coordination chemistry of 2-(2-pyridyl)-phosphinines and 2,2′-biphosphinines. No particular use for these complexes is stated. These compounds are merely suggested as phosphorous analogs of bipyridines.

In the first aspect of the present invention, the metal complex emits light when used in the light emitting device. In this regard, the metal complex may be fluorescent or phosphorescent. Preferably the metal complex is phosphorescent although the invention is not so limited.

In the metal complex having general formula I, preferably, Ar is coordinated directly to the metal (M) by the phosphorous atom.

Where the phosphorous in the metal complex according to the present invention coordinates directly to the metal, the ligand will be a strong field effect ligand. In fact, the ligand will have a stronger field effect than the corresponding ligand where nitrogen is in the place of the phosphorous. This has advantages as discussed above for pushing the energy levels of some of the d-orbitals of the metal up so as to disfavour energy loss through non-radiative decay of the excited state.

In one embodiment, L preferably is a bidentate ligand. Where the ligand L in the metal complex according to the present invention is a bidentate ligand, this has advantages in providing stability to the metal complex through the chelating effect of the bidentate ligand. Specifically, this has advantages over the well known PPh₃ and CO ligands.

Where the ligand L in the metal complex according to the present invention is a bidentate ligand, L preferably additionally comprises Ar′, which is a substituted or unsubstituted aryl or heteroaryl group. In this embodiment, Ar′ preferably is coordinated directly to the metal M in the metal complex. Ar preferably is conjugatively bound to Ar′. In this regard, Ar may be fused to Ar′ or linked via a single or double bond to Ar′.

Again, where the ligand L in the metal complex according to the present invention is a bidentate ligand, L could be a mixed donor ligand, for example P and C; or P and N.

Ar (and/or Ar′, where present) preferably is a substituted or unsubstituted six membered ring or a five membered ring.

Further preferably, in one embodiment, Ar (and/or Ar′, where present) contains more than one heteroatom. Preferably, the second heteroatom is N or P.

Examples of suitable bidentate ligands L are shown below by general formulae II to VII, which may be substituted or unsubstituted: 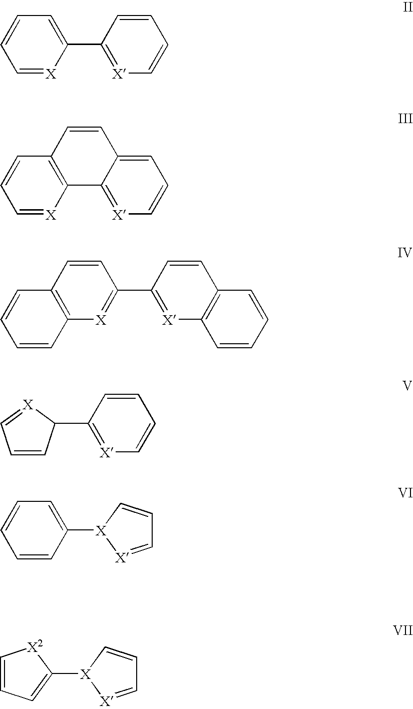
Where X, X′ and X² each independently is C, N, or O and where at least one of X, X′ and X² is P. Preferably, X′ in general formulae V, VI, and VII is P.

As discussed above, a ligand in a metal complex can have several roles. As such, in one embodiment L preferably is an emitting ligand. An example of an emitting ligand L is where L comprises a group having formula VIII: 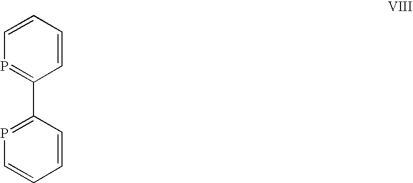
which is substituted or unsubstituted and L is directly coordinated to M in the metal complex via the two phosphorous atoms.

Where L is an emitting ligand, it may also be a strong field ligand.

In another embodiment, L preferably is not an emitting ligand. In this embodiment, L preferably is a strong field ligand. Such a ligand would be especially useful for stabilizing low oxidation state complexes such as W(O) and Re(I) complexes. Examples of strong field ligands L include those where L comprises a group selected from those having formula IX, X or XI: 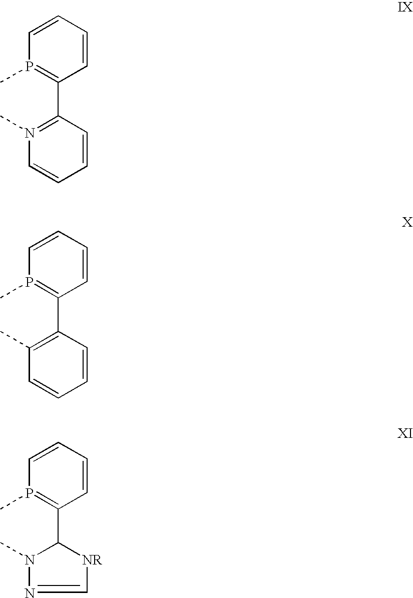
each being independently substituted or unsubstituted, wherein L is directly coordinated to M in the metal complex by the positions shown and each R independently is H or a substituent group such as an aryl, heteroaryl, alkyl or halide group.

As mentioned above, Ar (and/or Ar′, where present) in the metal complexes according to the present invention may be substituted or unsubstituted. As such, they may be functionalised with substituents. For example, Ar and/or Ar′ may be substituted with one or more solubilising groups in order to render the metal complex solution processable. This has advantages when preparing an LED including the metal complex since the metal complex thus may be deposited from solution when making the device.

Therefore, in one preferred embodiment L contains at least one solubilising substituent.

Further, Ar and/or Ar′ may be substituted with charge transport groups, which can be used to improve hole transport and/or electron transport in the system.

Therefore, in another preferred embodiment L contains a charge transporting substituent.

In still another preferred embodiment, L contains substituents which shift the emission colour of the complex.

In view of the above, particularly preferred substituents include fluorine or trifluoromethyl which may be used to blue shift the emission colour of the complex; carbazole which may be used to assist hole transport to the complex; bromine, chlorine or iodine which can serve to functionalise the ligand for attachment of further groups; and alkyl or alkoxy groups or dendrons which may be used to obtain or enhance solution processability of the metal complex.

Turning to the metal M in the complex, suitable metals M include:
lanthanide metals such as cerium, samarium, europium, terbium, dysprosium, thulium, erbium and neodymium;
d-block metals, in particular those in rows 2 and 3 i.e. elements 39 to 48 and 72 to 80, in particular ruthenium, tungsten, copper, cromium, molybdenum, rhodium, palladium, rhenium, osmium, iridium, platinum and gold. Rhenium is particularly preferred; and
metals forming fluorescent complexes such as aluminium, beryllium, zinc, mercury, cadmium and gallium.

Typically, the metal complex will contain other ligands (coordinating groups) in addition to L.

Of course, the metal complex may contain more than one ligand L, where each L may be the same or different.

The ligands in the metal complex (other than L) can be monodentate, bidentate or tridentate. For bidentate and tridentate ligands, the coordinating atoms may be linked so as to form an 7, 6, 5 or 4 membered ring when coordinated to M. A 6 membered ring is preferred and a 5 membered ring is most preferred. Suitable ligands will be known to those skilled in the art.

An example of a tridentate ligand is: 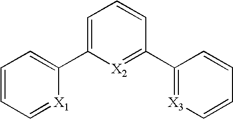
where X₁, X₂ and X₃ independently are selected from N, C, O and S. Preferably, X₁=X₂=X₃=N.

A preferred group to be coordinated to M is a phenolic group:

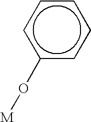

As such, a particularly preferred bidentate ligand is a quinolinate.

Suitable coordinating groups for the f-block metals include oxygen or nitrogen donor systems such as carboxylic acids, 1,3-diketonates, hydroxy carboxylic acids, Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal.

The sharp emission is generally narrow, resulting in a pure colour emission useful for display applications.

The d-block metals preferably form complexes with carbon or nitrogen donors such as porphyrin or bidentate ligands of formula (XII): 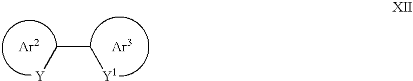
wherein Ar² and Ar³ may be the same or different and are independently selected from optionally substituted aryl or heteroaryl; Y¹ and Y may be the same or different and are independently selected from carbon or nitrogen; and Ar² and Ar³ may be fused together. Ligands wherein Y is carbon and Y¹ is nitrogen, or wherein Y and Y¹ are both nitrogen are particularly preferred.

Examples of bidentate ligands are illustrated below:

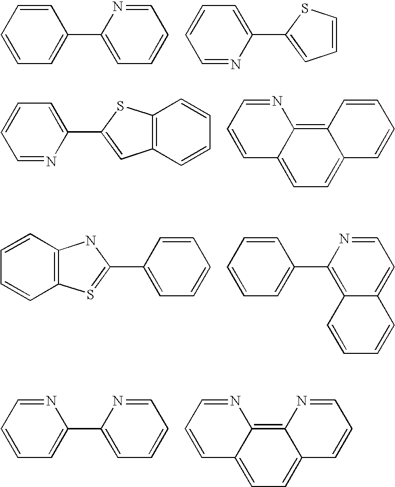

One or both of Ar² and Ar³ may carry one or more substituents. Preferred substituents are as discussed above.

Other ligands suitable for use with d-block elements include diketonates, in particular acetylacetonate (acac); quinolinate, triarylphosphines and pyridine, each of which may be substituted.

In the light-emitting device according to the first aspect of the present invention the metal complex optionally is present in the light emissive layer together with a host material. The metal complex may be mixed physically with the host material in the light emissive layer or may be covalently bound to the host material. In one preferred embodiment, the metal complex is blended with the host material in the light emissive layer. In another embodiment the metal complex is provided as a repeat unit, side chain substituent and/or end-group of a polymer. In another embodiment the metal complex is provided in a dendrimer. The core of the dendrimer will comprise the metal M.

The present invention therefore provides a blend comprising a metal complex as defined above and a host material. The present invention further provides a polymer containing a metal complex as defined above as a repeat unit, side chain substituent and/or end group of the polymer. The present invention still further provides a dendrimer containing a metal complex as defined above.

The host material may also have charge transporting properties. Hole transporting host materials are particularly preferred such as the optionally substituted hole-transporting arylamine having the following formula: 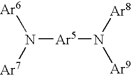
wherein Ar⁵ is an optionally substituted aromatic group, such as phenyl, or 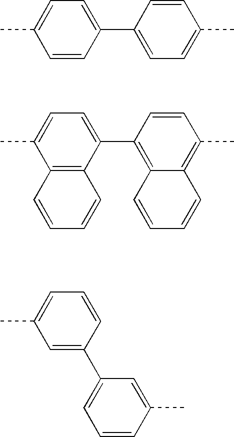
and Ar⁶, Ar⁷, Ar⁸ and Ar⁹ are optionally substituted aromatic or heteroaromatic groups (Shi et al (Kodak) U.S. Pat. No. 5,554,450. Van Slyke et al, U.S. Pat. No. 5,061,569. So et al (Motorola) U.S. Pat. No. 5,853,905 (1997)). Ar is preferably biphenyl. At least two of Ar⁶, Ar⁷, Ar⁸ and Ar⁹ may be bonded to either a thiol group, or a group containing a reactive unsaturated carbon-carbon bond. Ar⁶ and Ar⁷ and/or Ar⁸ and Ar⁹ are optionally linked to form a N containing ring, for example so that the N forms part of a carbazole unit e.g. 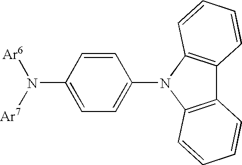
Host materials may alternatively possess electron transporting properties. Examples of electron transporting host materials are azoles, diazoles, triazoles, oxadiazoles, benzoxazoles, benzazoles and phenanthrolines, each of which may optionally be substituted. Particularly preferred substituents are aryl groups, in particular phenyl. oxadiazoles, in particular aryl-substituted oxadiazoles. These host materials may exist in small molecule form or may be provided as repeat units of a polymer, in particular as repeat units located in the backbone of a polymer or as substituents pendant from a polymer backbone. Specific examples of electron transporting host materials include 3-phenyl-4-(1-naphthyl)-5-phenyl-1,2,4-triazole and 2,9-dimethyl-4,7-diphenyl-phenanthroline.

Host materials may be bipolar, i.e. capable of transporting holes and electrons. Suitable bipolar materials preferably contain at least two carbazole units (Shirota, J. Mater. Chem., 2000, 10, 1-25). In one preferred compound, both Ar⁶ and Ar⁷ and Ar⁸ and Ar⁹ as described above are linked to form carbazole rings and Ar⁵ is phenyl. Alternatively, a bipolar host material may be a material comprising a hole transporting segment and an electron transporting segment. An example of such a material is a polymer comprising a hole transporting segment and an electron transporting segment as disclosed in WO 00/55927 wherein hole transport is provided by a triarylamine repeat unit located within the polymer backbone and electron transport is provided by a conjugated polyfluorene chain within the polymer backbone. Alternatively, the properties of hole transport and electron transport may be provided by repeat units pendant from a conjugated or non-conjugated polymer backbone.

Specific examples of “small molecule” hosts include 4,4′-bis(carbazol-9-yl)biphenyl), known as CBP, and (4,4′,4″-tris(carbazol-9-yl)triphenylamine), known as TCTA, disclosed in Ikai et al. (Appl. Phys. Lett., 79 no. 2, 2001, 156); and triarylamines such as tris-4-(N-3-methylphenyl-N-phenyl)phenylamine, known as MTDATA.

Homopolymers and copolymers may be used as hosts, including optionally substituted polyarylenes such as polyfluorenes, polyspirofluorenes, polyindenofluorenes or polyphenylenes as described above with respect to the hole transporting layer. Specific examples of host polymers disclosed in the prior art include poly(vinyl carbazole) disclosed in, for example, Appl. Phys. Lett. 2000, 77(15), 2280; polyfluorenes in Synth. Met. 2001, 116, 379, Phys. Rev. B 2001, 63, 235206 and Appl. Phys. Lett. 2003, 82(7), 1006; poly[4-(N-4-vinylbenzyloxyethyl, N-methylamino)-N-(2,5-di-tert-butylphenylnapthalimide] in Adv. Mater. 1999, 11(4), 285; poly(para-phenylenes) in J. Mater. Chem. 2003, 13, 50-55; poly[9,9′-di-n-hexyl-2,7-fluorene-alt-1,4-(2,5-di-n-hexyloxy)phenylene] as a host for both fac-tris(2-phenylpyridine) iridium(III) and 2,3,7,8,12,13,17,18-octaethyl-21H,23H-porphyrin platinum(II) in J. Chem. Phys. (2003), 118(6), 2853-2864; a random copolymer host of dioctylfluorene and dicyano-benzene in Mat. Res. Symp. Spring Meeting 2003 Book of Abstracts, Heeger, p. 214; and an AB copolymer of a fluorene repeat unit and phenylene repeat unit is disclosed in Mat. Res. Soc. Symp. Proc. 708, 2002, 131.

The concentration of the phosphorescent light-emitting dopant in the host material should be such that the film has a high electroluminescent efficiency. If the concentration of the emissive species is too high, quenching of luminescence can occur. A concentration in the range 0.01-49 wt %, more preferably 0.5-10 wt %, most preferably 1-3 wt % is generally appropriate.

The host material and the electroluminescent material may be provided as separate materials as described above. Alternatively, they may be components of the same molecule. For example, a phosphorescent metal complex may be provided as repeat unit, sidechain substituent or end-group of a host polymer as disclosed in, for example, WO 02/31896, WO 03/001616, WO 03/018653 and EP 1245659. Likewise, a “small molecule” host material may be bound directly to a ligand of a phosphorescent metal complex.

With reference to FIG. 1, an organic light emitting diode according to the invention may comprise a substrate 1, an anode 2 (preferably of indium tin oxide), a layer 3 of organic hole injection material, an electroluminescent layer 4 and a cathode 5.

As shown in FIG. 1, usually, the anode is provided on a substrate in the LED according to the present invention. Optical devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

Although not essential, the presence of a hole injection layer between the anode and the light emissive layer is desirable as it assists hole injection from the anode into the emissive layer. Examples of organic hole injection materials include polyethylenedioxythiophene (PEDT) with a suitable counterion such as poly(styrene sulfonate) as disclosed in EP 0901176 and EP 0947123, or polyaniline as disclosed in U.S. Pat. No. 5,723,873 and U.S. Pat. No. 5,798,170.

Charge transporting layers (not shown) comprising semiconducting materials may also be provided. A hole transporting layer may be provided between the anode and the emissive layer and an electron transporting layer may be provided between the cathode and the emissive layer.

The cathode is selected so that electrons are efficiently injected into the device and as such may comprise a single conductive material such as a layer of aluminium. Alternatively, it may comprise a plurality of metals, for example a bilayer of calcium and aluminium as disclosed in WO 98/10621. A thin layer of dielectric material such as lithium fluoride optionally may be provided between the light emissive layer and the cathode to assist electron injection as disclosed in, for example, WO 00/48258. Preferably, the cathode comprises a layer comprising a metal having a workfunction less than 3.5 eV, more preferably less than 3.0 eV.

The device is preferably encapsulated with an encapsulant to prevent ingress of moisture and oxygen. Suitable encapsulants include a sheet of glass, films having suitable barrier properties such as alternating stacks of polymer and dielectric as disclosed in, for example, WO 01/81649 or an airtight container, optionally with a desiccant, as disclosed in, for example, WO 01/19142.

In a practical device, at least one of the electrodes is semi-transparent in order that light may be emitted. Where the anode is transparent, it typically comprises indium tin oxide. Examples of transparent cathodes are disclosed in, for example, GB 2348316.

Turning now to the second aspect of the present invention, this provides a method of making a light-emitting device as defined in relation to the first aspect of the present invention comprising the steps of forming the anode, the cathode and the light emissive layer so that the light emissive layer is located between the anode and the cathode.

Where possible, it is preferred that the light emissive layer is formed by solution processing. Suitable techniques for solution processing will be well known to a person skilled in this art.

As will be appreciated from the above, the present invention provides some novel metal complexes for use in LED. As such, a sixth aspect of the present invention provides a metal complex comprising the group having general formula I:
M-L I
where M is the metal and L is a ligand, and L comprises a group having general formula XII or XIII where L is directly coordinated to M in the metal complex by the positions shown 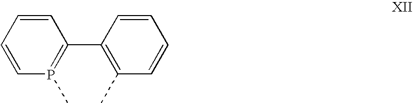
which is substituted or unsubstituted 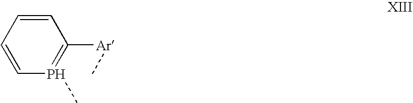
which is substituted or unsubstituted and where Ar′ is a 5 membered aryl or heteroaryl ring. Ar′ may be further defined as described above in relation to the first aspect of the present invention.

Possible routes for synthesising metal complexes comprising a group having general formula I are described below.

1) Iridium Complexes

A charged iridium complex may be formed by reacting the iridium phenylpyridine dimer with the biphosphinine ligand. This will form a charged complex but it would be analogous to the known complex [Ir(ppy)₂(X₂bpy)][PF₆], (X=^{t}Bu) which was recently described (J. Am. Chem. Soc., 2004, 126, 2763).

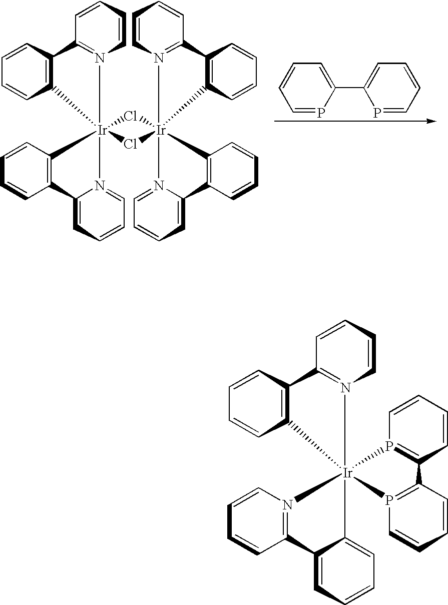

Similarly a neutral complex could be formed using a a ligand with one P-donor ring and one cyclometallated phenyl ring.

2) Rhenium Complex

A rhenium complex may be formed by reacting a biphosphinine ligand with Re(CO)₅Cl.

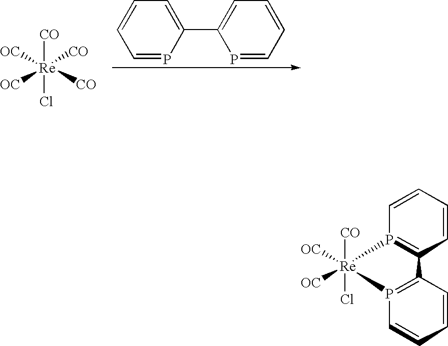

The simplest known biphosphinine ligand is the 4,4′,5,5′-tetramethyl derivative (tmbp), below:

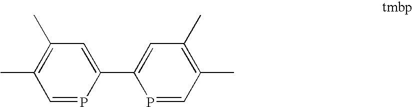

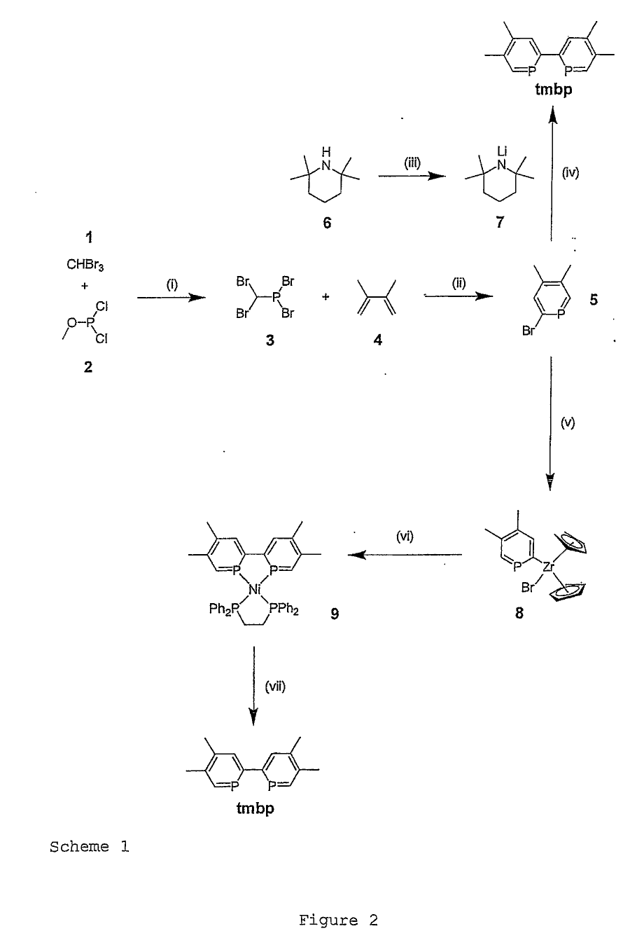

The synthesis of tmbp has been achieved by two routes as shown in scheme 1 in FIG. 2. The details of these synthesis will be briefly discussed.

Reaction conditions in Scheme 1 are as follows:

(i) AlBr₃, PBr₃, 55%;¹ (ii) NEt₃, THF, 40° C., 2 hr; NEt₃, THF, 70° C., 4 hr, 43%;² (iii) nBuLi, toluene, −78° C., RT, 100%;³ (iv) toluene, 100° C., 1 hr, 30%;³ (v) ZrCp₂Cl₂, THF, −78° C.; 30° C., 1 hr;⁴ (vi) [Ni(dppe)Cl₂], THF, 80° C., 45 min;⁴ (vii) C₂Cl₆, THF, −20° C., 30 min, 55% from 5.⁶ Steps (v)-(vii) can be performed in one pot without isolation of the intermediates.

Both routes to tmbp require the bromophosphinine, 5. This is synthesised in two steps: the synthesis of dibromomethyldibromophosphine and it's subsequent condensation with 2,3-dimethylbutadiene. The original route to tmbp is via a coupling of 5 in the presence of LiTMP. This gives tmbp directly in 30% yield from 5.

An alternative route to tmbp has been reported which makes use of a zirconium intermediate, 8, which is then coupled in the presence of [Ni(dppe)Cl₂]. The three steps in this route can be carried out in one pot without the need to isolate the intermediates and the overall yield from 5 is 55%.

### REFERENCES

1) J. Gen. Chem. USSR (Engl. Transl.), 54, 7, 1984, 1354-1360.
2) Polyhderon, 9, 7, 1990, 991-997.
3) Bull. Soc. Chim. Fr., 131, 1991, 330-334.
4) J. Org. Chem, 63, 1998, 4826-4828.

1. A light-emitting device comprising:
an anode;
a cathode;
a light emissive layer located between the anode and the cathode, said light emissive layer comprising a metal complex for emitting light; the metal complex comprising the group having general formula I:
M-L (I)
where M is a metal and L is a ligand, and L comprises Ar which is a substituted or unsubstituted heteroaryl ring; characterised in that the heteroaryl ring contains at least one phosphorous atom.

2. A light-emitting device according to claim 1, wherein Ar is coordinated to M by the phosphorous atom.

3. A light-emitting device according to claim 1, wherein L is a bidentate ligand.

4. A light-emitting device according to claim 3, wherein L additionally comprises Ar′ which is a substituted or unsubstituted aryl or heteroaryl group and Ar′ is coordinated directly to M in the metal complex.

5. A light-emitting device according to claim 1, wherein Ar and/or Ar′ independently is a substituted or unsubstituted six membered ring.

6. A light-emitting device according to claim 1, wherein Ar and/or Ar′ independently contains more than one heteroatom.

7. A light-emitting device according to claim 1, wherein L is an emitting ligand.

8. A light-emitting device according to claim 7, wherein L comprises a group having formula VIII: 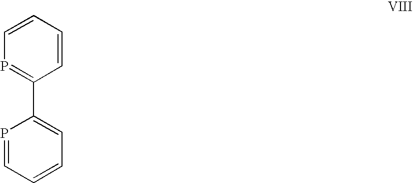
which is substituted or unsubstituted and L is directly coordinated to M in the metal complex via the two phosphorous atoms.

9. A light-emitting device according to claim 1, wherein L is not an emitting ligand.

10. A light-emitting device according to claim 9, wherein L comprises a group selected from those having formula IX, X or XI: 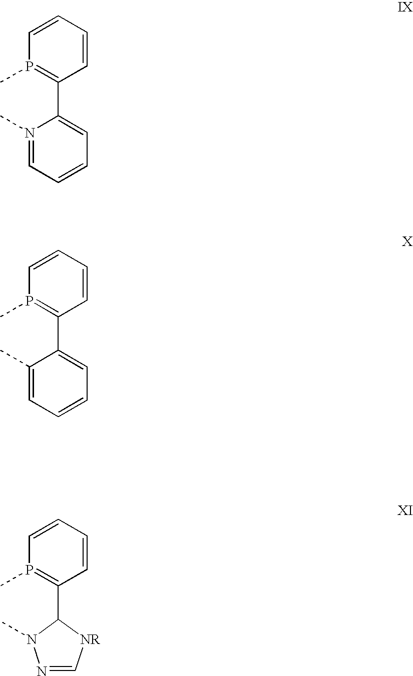
each being independently substituted or unsubstituted, wherein L is directly coordinated to M in the metal complex by the positions shown and each R independently is H or an aryl, heteroaryl, alkyl, or halide group.

11. A light-emitting device according to claim 1, wherein L contains a solubilising substituent.

12. A light-emitting device according to claim 1, wherein L contains a charge transporting substituent.

13. A light-emitting device according to claim 1, wherein the metal complex is blended with a host material in the light emissive layer.

14. A light-emitting device according to claim 1, wherein a polymer or dendrimer contains the metal complex.

15. A method of making a light-emitting device as defined in claim 1, comprising the steps of forming the anode, the cathodes and the light emissive layer so that the light emissive layer is located between the anode and the cathode.

16. A method according to claim 15, wherein the light emissive layer is formed by solution processing.

17. (canceled)

18. A blend comprising a metal complex as defined in claim 1, and a host material.

19. A polymer or dendrimer containing a metal complex as defined in claim 1.

20. A metal complex comprising the group having general formula I:
M-L (I)
where M is the metal and L is a ligand, and L comprises a group having general formula XII or XIII where L is directly coordinated to M in the metal complex by the positions shown 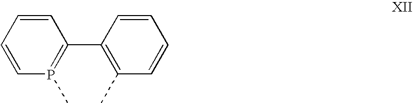
which is substituted or unsubstituted 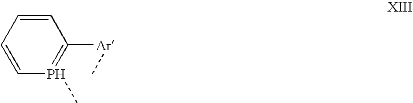
which is substituted or unsubstituted and where Ar′ is a 5 membered aryl or heteroaryl ring.
